(19) United States
(12) Patent Application Publication
(10) Pub. No.: US 2015/0207030 A1
(43) Pub. Date: Jul. 23, 2015

(54) SEMICONDUCTOR LIGHT EMITTING STRUCTURE

(71) Applicant: Lextar Electronics Corporation, Hsinchu (TW)

(72) Inventors: Ming-Chang Tang, Taichung City (TW); Nai-Wei Hsu, Tainan City (TW)

(21) Appl. No.: 14/324,409

(22) Filed: Jul. 7, 2014

(30) Foreign Application Priority Data
Jan. 23, 2014 (TW) 103102448

(51) Int. Cl. H01L 33/20

(52) U.S. Cl. CPC H01L 33/20; H01L 2933/0091

(57) ABSTRACT

A semiconductor light emitting structure comprising a substrate, a patterned structure, a first semiconductor layer, an active layer and a second semiconductor layer is provided. The substrate has a first surface and a second surface opposite to the first surface. The patterned structure is formed on the first surface of the substrate. The patterned structure comprises a plurality of pyramid structures with different sizes. The first semiconductor layer is disposed on the first surface. The active layer is disposed on the first semiconductor layer. The second semiconductor layer is disposed on the active layer.

This application claims the benefit of Taiwan application Serial No. 103102448, filed Jan. 23, 2014, the subject matter of which is incorporated herein by reference.

### BACKGROUND OF THE INVENTION

1. Field of the Invention

The invention relates in general to a semiconductor light emitting structure, and more particularly to a semiconductor light emitting structure capable of increasing light extraction efficiency.

2. Description of the Related Art

The light-emitting diode (LED) emits a light by converting electric energy into photo energy. The LED is mainly composed of semiconductors. Of the semiconductors, those having a larger ratio of holes carrying positive electricity are referred as P-type semiconductors, and those having a larger ratio of electrons carrying negative electricity are referred as N-type semiconductors. The joint connecting a P-type semiconductor and an N-type semiconductor forms a PN joint. When a voltage is applied to the positive and negative electrodes of an LED chip, the electrons and the holes will be combined and then emit energy in a form of light.

Since most substrates of LED are sapphire substrates or silicon substrates and have a large refractive index, the light emitted towards the substrate may easily be reflected by the substrate. Thus, a portion of the light is contained within the LED and cannot be extracted, and the light extraction efficiency will decrease.

### SUMMARY OF THE INVENTION

The invention is directed to a semiconductor light emitting structure capable of increasing light extraction efficiency by changing the output angle of light.

According to one embodiment of the present invention, a semiconductor light emitting structure comprising a substrate, a patterned structure, a first semiconductor layer, an active layer and a second semiconductor layer is provided. The substrate has a first surface and a second surface opposite to the first surface. The patterned structure is formed on the first surface of the substrate. The patterned structure comprises a plurality of pyramid structures with different sizes. The first semiconductor layer is disposed on the first surface. The active layer is disposed on the first semiconductor layer. The second semiconductor layer is disposed on the active layer.

The above and other aspects of the invention will become better understood with regard to the following detailed description of the preferred but non-limiting embodiment(s). The following description is made with reference to the accompanying drawings.

### BRIEF DESCRIPTION OF THE DRAWINGS

FIG. 1 is a schematic diagram of a semiconductor light emitting structure according to an embodiment of the invention.

FIG. 2 is a top view of a patterned structure.

FIGS. 3A and 3B are schematic diagrams of pyramid structures.

FIG. 3C is a schematic diagram of pyramid structures according to another embodiment.

FIGS. 4A and 4B are schematic diagrams of a light emitted out of a semiconductor light emitting structure after having been reflected twice.

FIGS. 5A and 5B are photos of pyramid structures taken by a microscopy.

### DETAILED DESCRIPTION OF THE INVENTION

According to a semiconductor light emitting structure disclosed in an example of the present embodiment, a patterned structure is formed on a substrate, such that a surface of the substrate has a plurality of protrusions and/or concaves with specific geometric shapes. The protrusions have different sizes or shapes, such as pyramid structures with different sizes, pyramid structures with different sizes and shapes, or pyramid structures with different sizes but the same shape.

In an example of the present embodiment, the pyramid structures with different size can be pyramid structures with different heights, pyramid structures with different heights and bottom widths or pyramid structures with different heights but the same bottom width. For example, a ratio of the height to the bottom width of the pyramid structures is preferably between 0.2˜0.7, but the invention is not limited thereto, and the ratio can also be between 0.1˜1.

In an example of the present embodiment, the pyramid structures can have different shapes such as cone, triangular pyramid, flat-topped cone, flat-topped triangular pyramid or other shapes. The bottom of the pyramid structures can be circular, triangular, quadrangular, pentagonal or hexagonal. The pyramid structures formed on a surface of the substrate can have the same or different shapes. The positions of pyramid structures with the same or different shapes can be arranged in interlacing manner on the surface of the substrate to form a patterned structure with interlacing heights and have different sizes.

A number of embodiments are disclosed below for elaborating the invention. However, the embodiments of the invention are exemplary and explanatory only, not for limiting the scope of protection of the invention.

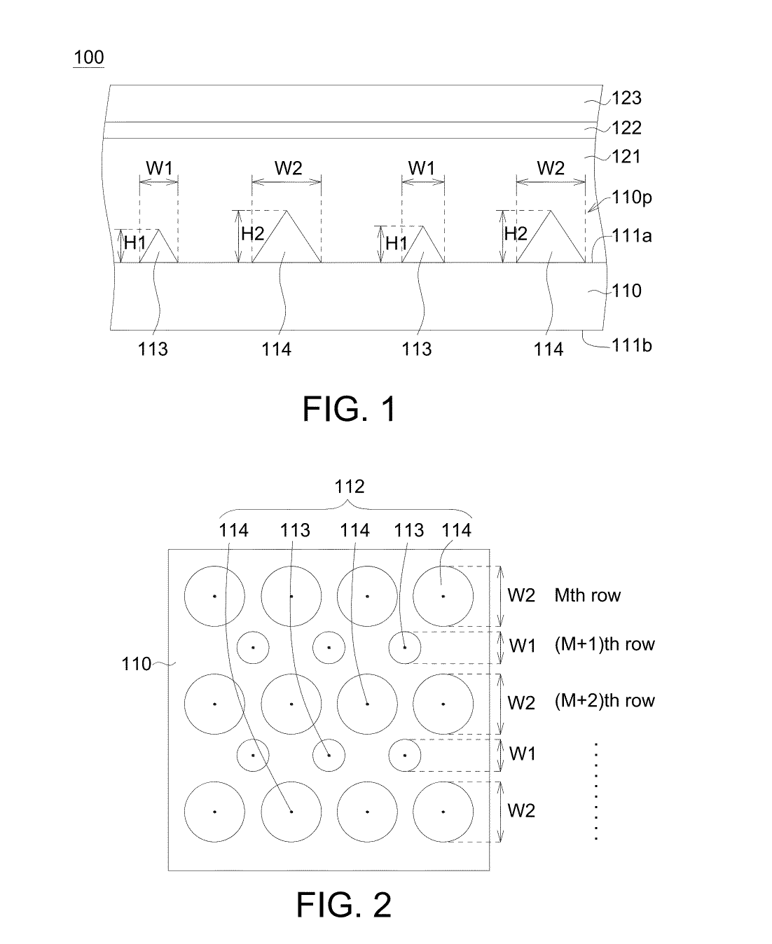

Please refer to FIGS. 1 and 2. FIG. 1 is a schematic diagram of a semiconductor light emitting structure 100 according to an embodiment of the invention. FIG. 2 is a top view of a pyramid structure 112. The semiconductor light emitting structure 100 comprises a substrate 110, a patterned structure 110p, a first semiconductor layer 121, an active layer 122 and a second semiconductor layer 123. The substrate 110 has a first surface 111a and a second surface 111b opposite to the first surface 111a. The patterned structure 110p is disposed on the first surface 111a of the substrate 110 and comprises a plurality of pyramid structures 112 with different sizes. The first semiconductor layer 121 is disposed on the first surface 111a. The active layer 122 is disposed on the first semiconductor layer 121. The second semiconductor layer 123 is disposed on the active layer 122.

As indicated in FIG. 1, the pyramid structures 112 are projected from the first surface 111a of the substrate 110 to form a coarsened surface. The first semiconductor layer 121 can directly or indirectly cover each pyramid structure 112. The size of the pyramid structures 112 is between 0.1˜5 μm, and preferably between 0.5˜2 μm. In an embodiment, the pyramid structures 112 with different size and/or shapes can be formed by way of dry etching process, wet etching process or mixed dry/wet etching process.

In the commonly used dry etching process, gas is used as a main etching medium, and gas reaction is activated by plasma energy. Molecules of the etching gas are decomposed by plasma energy to generate highly reactive molecules capable of quickly etching the material of the substrate 110. Furthermore, the gas molecules are ionized by plasma energy to carry charges. The substrate 110 is disposed on a cathode carrying negative charges. When the ions with positive charges are attracted by the cathode and accelerate towards the cathode, the ions will bombard the surface of the substrate 110 to form a patterned structure 110p with specific geometric shape. Also, the commonly used mixed dry/wet etching process, which combines physical ion bombardment and chemical etching, advantageously possesses anisotropic etching and high etching selectivity. A portion of the surface is not bombarded by ions and reserves the original shape, while the other portion of the surface is bombarded by ions first and then reacts with the etching gas, such that the surface can have different shapes and the patterned structure 110p with specific geometric shape can be formed.

Please refer to FIG. 1. The pyramid structures 112 comprise a plurality of pyramid structures with first size 113 and a plurality of pyramid structures with second size 114, and the pyramid structures with first and second sizes 113 and 114 are interlaced on the first surface 111a of the substrate 110. The pyramid structures with first size 113 have a first height H1 and a first bottom width W1. The pyramid structures with second size 114 have a second height H2 and a second bottom width W2. In an embodiment, the height of the pyramid structures with first size 113 can be smaller than that of the pyramid structures with second size 114, that is, H1<H2, and the bottom width of the pyramid structures with first size 113 can be smaller than that of the pyramid structures with second size 114, that is, W1<W2.

In an unillustrated embodiment, the height of the pyramid structures with first size 113 can be smaller than that of the pyramid structures with second size 114, but the bottom width of pyramid structures with first size 113 can be larger than or equal to the pyramid structures with second size 114. Or, the height of the pyramid structures with first size 113 can be larger than that of the pyramid structures with second size 114, but the bottom width of the pyramid structures with first size 113 can be smaller than that of the pyramid structures with second size 114.

In an embodiment, a ratio of the height to the bottom width of the pyramid structures with first and second sizes 113 and 114 is between 0.2˜0.7, but the invention is not limited thereto, and the ratio can also be between 0.1˜1.

Please refer to FIG. 2. The pyramid structures with first size 113 and the pyramid structures with second size 114 are arranged in the form of an island array at equal or unequal intervals. As indicated in FIG. 2, the pyramid structures with first size 113 at the (M+1)th row are interposed between the pyramid structures with second size 114 at the Mth row and the pyramid structures with second size 114 at the (M+2)th row, wherein the first size is smaller than the second size and M is an integer greater or equal to 1. Since the pyramid structures 114 with a larger size surround the pyramid structures 113 with a smaller size, the number of pyramids per unit area of the substrate 110 is increased. Moreover, two adjacent pyramid structures 113 and 114 along a diagonal direction have different sizes, so that the pyramid structures 113 and 114 with different heights are interlaced to form the patterned structure 110p.

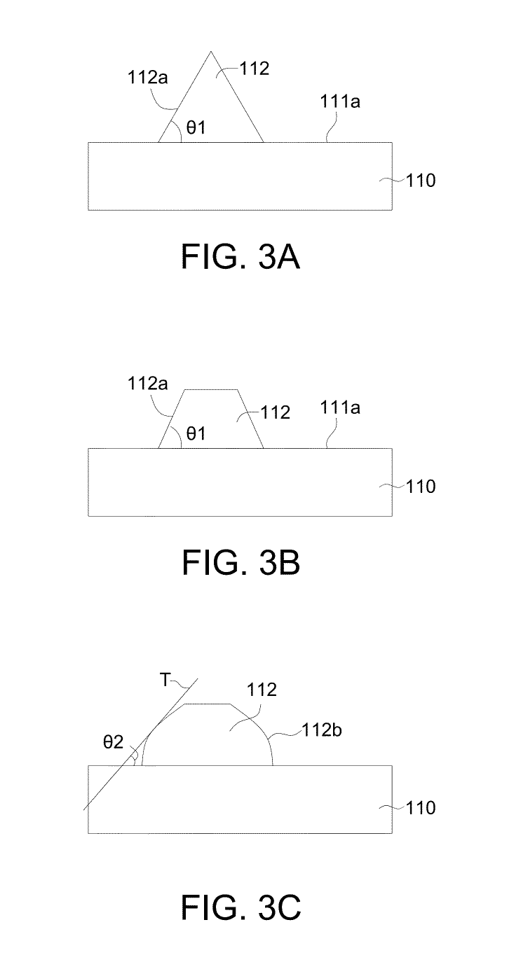

Referring to FIGS. 3A and 3B, schematic diagrams of pyramid structures 112 are shown. The pyramid structures 112 are, for example, cones, triangular pyramids, flat-topped cones or flat-topped triangular pyramids, and each pyramid structure 112 has a lateral surface 112a which forms an angle θ1 with the first surface 111a of the substrate 110. The angle θ1 is between 5˜85°, and preferably between 30˜60°.

Referring to FIG. 3C, a schematic diagram of pyramid structures 112 according to another embodiment is shown. The lateral surface 112b of the pyramid structures 112 is, for example, a curved surface whose tangent line T forms an angle θ2 with the first surface 111a of the substrate 110, wherein the angle θ2 is between 5˜85° and progressively increases downward from an apex of pyramid. In an embodiment, the curvature of the curved surface of the pyramid structures 112 can be controlled by adjusting the etching direction in the dry etching process or the mixed dry/wet etching process so that the surface of the pyramid structures 112 can have a specific shape.

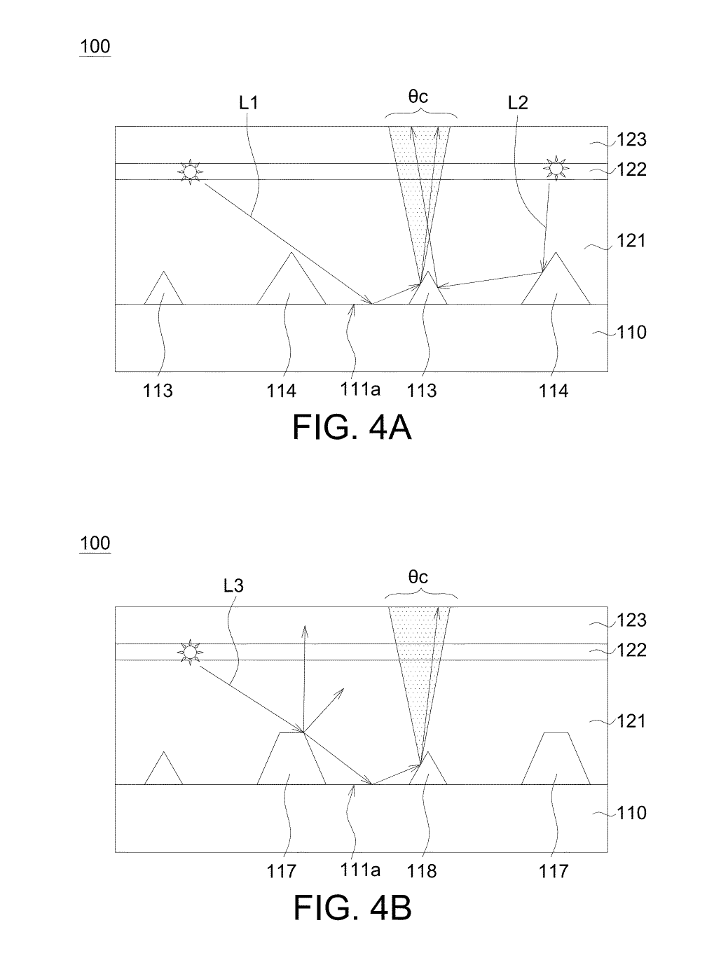

Referring to FIGS. 4A and 4B, schematic diagrams of a light emitted out of a semiconductor light emitting structure 100 after having been reflected twice are shown. The first semiconductor layer 121 and the second semiconductor layer 123 can be doped with a pentavalent element (such as phosphorus) and a trivalent element (such as aluminum) to form an N-type semiconductor layer and a P-type semiconductor layer respectively. When a voltage is applied to the first semiconductor layer 121 and the second semiconductor layer 123, electrons and holes, driven be the voltage, flow towards a PN junction (that is, the active layer 122) from two electrodes respectively, such that the electrons and the holes in the active layer 122 are combined and release energy which is emitted in the form of light.

As indicated in FIG. 4A, after a first light L1 proceeding towards the substrate 110 is firstly reflected by the first surface 111a of the substrate 110 and then is secondly reflected by the pyramid structures with first size 113, the first light L1 proceeds away from the substrate 110, and the output angle of the first light L1 is changed. Besides, after a second light L2 proceeding towards the substrate 110 is firstly reflected by the pyramid structures with second size 114 and then is secondly reflected by the pyramid structures with first size 113, the second light L2 proceeds away from the substrate 110 and the output angle of the second light L2 is changed. In an embodiment, when the output angle of the first light L1, having been secondly reflected, falls within the range of a critical angle θc (indicating the range of the critical angle of the light L1 only), the first light L1 can be directly emitted out of the upper surface without being reflected back, so that the light extraction efficiency is increased.

As indicated in FIG. 4B, if the pyramid structures 117 with second size are flat-topped cones or flat-topped triangular pyramids, a portion of the third light L3 proceeding towards the substrate 110 is directly reflected or scattered by the flat-topped surface of the cone and another portion of the third light L3 is firstly reflected by the first surface 111a of the substrate 110 and then is secondly reflected by the pyramid structures with first size 118. Then, the other portion of the light L3 proceeds away from the substrate 110, and the output angle of the third light L3 is changed. In an embodiment, when the output angle of the third light L3, having been firstly or secondly reflected, falls within the range of the critical angle θc, the third light L3 can be directly emitted out of the upper surface without being reflected back, so that the light extraction efficiency is increased.

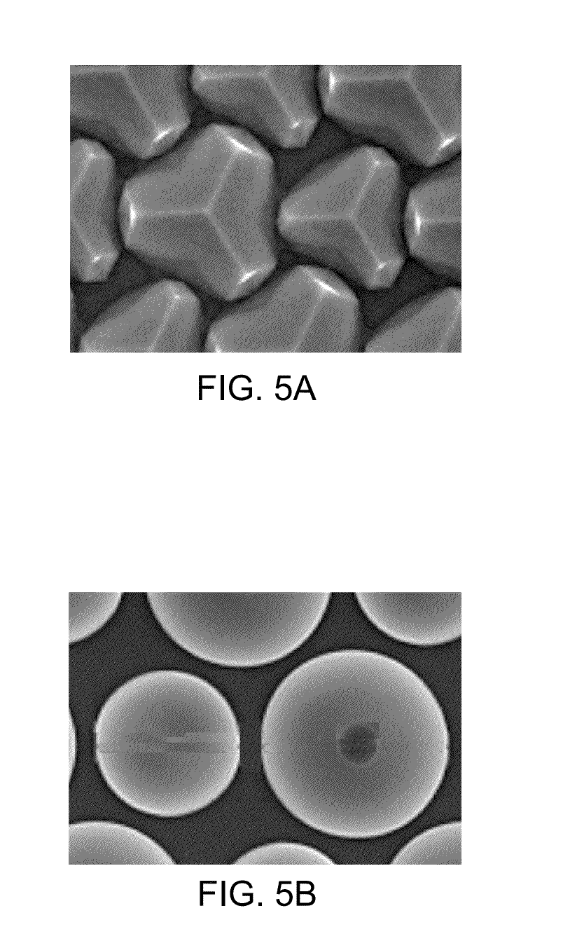

In an embodiment, the substrate 110 can be a sapphire substrate, a silica substrate or a silicon substrate. The first surface 111a of the substrate 110 can be patterned to form a plurality of pyramid structures 112 with different sizes. Referring to FIGS. 5A and 5B, photos of pyramid structures taken by a microscopy are shown. As indicated in the photos of FIGS. 5A and 5B, the substrate can be patterned to from a plurality of pyramid structures with different sizes. The pyramid structures 112 can reflect or scatter the light proceeding towards the substrate 110. Since the light can be scattered outwards, full reflection will be hard to occur and the light extraction efficiency is increased.

According to the semiconductor light emitting structure disclosed in above embodiments of the invention, pyramid structures with different sizes are used to change the output angle of the light so that the light extraction efficiency is increased. In comparison to the semiconductor light emitting structure which uses patterned structure with single size or shape to change the output angle of the light, the semiconductor light emitting structure of the invention avoids full reflection which occurs when the output angle of the light is outside the range of the critical angle.

While the invention has been described by way of example and in terms of the preferred embodiment (s), it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A semiconductor light emitting structure, comprising:
a substrate having a first surface and a second surface opposite to the first surface;
a patterned structure disposed on the first surface of the substrate, wherein the patterned structure comprises a plurality of pyramid structures with different sizes;
a first semiconductor layer disposed on the first surface;
an active layer disposed on the first semiconductor layer; and
a second semiconductor layer disposed on the active layer.

2. The semiconductor light emitting structure according to claim 1, wherein the pyramid structures have the same shape or different shapes, and have different heights and bottom widths, and the shapes of the pyramid structures comprise cone, triangular pyramid, flat-topped cone or flat-topped triangular pyramid.

3. The semiconductor light emitting structure according to claim 2, wherein a ratio of the height to the bottom width of the pyramid structures is between 0.2˜0.7.

4. The semiconductor light emitting structure according to claim 1, wherein each of the pyramid structures has a lateral surface, which forms an angle of 5°˜85° with the first surface.

5. The semiconductor light emitting structure according to claim 4, wherein the lateral surface is a curved surface whose tangent line forms an angle with the first surface, and the angle progressively increases downward from an apex of pyramid.

6. The semiconductor light emitting structure according to claim 2, wherein the pyramid structures comprise a plurality of pyramid structures with first size and a plurality of pyramid structures with second size, the pyramid structures with first and second sizes are interlaced on the first surface.

7. The semiconductor light emitting structure according to claim 6, wherein the pyramid structures with first and second sizes are arranged in the form of an island array at equal or unequal intervals.

8. The semiconductor light emitting structure according to claim 6, wherein a height of the pyramid structures with first size is smaller than that of the pyramid structures with second size.

9. The semiconductor light emitting structure according to claim 6, wherein a bottom width of the pyramid structures with first size is smaller than that of the pyramid structures with second size.

10. The semiconductor light emitting structure according to claim 6, wherein a ratio of the height to the bottom width of the pyramid structures with first and second sizes is between 0.2˜0.7.

11. The semiconductor light emitting structure according to claim 1, wherein the substrate is a sapphire substrate, a silica substrate or a silicon substrate.
